(19) United States
(12) Patent Application Publication
(10) Pub. No.: US 2014/0199846 A1
(43) Pub. Date: Jul. 17, 2014

(54) METHOD OF MANUFACTURING SEMICONDUCTOR DEVICE

(71) Applicant: Lingkuan Meng, Beijing (CN)

(72) Inventor: Lingkuan Meng, Beijing (CN)

(21) Appl. No.: 13/883,834

(22) PCT Filed: Sep. 5, 2012
(86) PCT No.: PCT/CN12/81007

§ 371 Date: May 7, 2013

(30) Foreign Application Priority Data
Aug. 21, 2012 (CN) 201210300046.6

(51) Int. Cl. H01L 21/768

(52) U.S. Cl. CPC H01L 21/76816
USPC 438/700

(57) ABSTRACT

A method of manufacturing a semiconductor device is disclosed. The method may comprise: etching a plurality of first openings in an interlayer dielectric layer on a substrate; forming an opening modifying layer in the plurality of first openings; and etching the opening modifying layer until the substrate is exposed, resulting in a plurality of second openings, wherein the second openings have a depth-to-width ratio greater than that of the first openings. In this way, a deep hole with a relatively large dimension can be formed in silicon oxide by conventional photolithography processes. After that, a film of silicon nitride can be deposited into the hole to achieve a desired CD, and then etched with the fluorocarbon gas(es) to implement an arrangement with a relatively great depth-to-width ratio.

### CROSS-REFERENCE TO RELATED APPLICATION(S)

The present application claims priority to Chinese Application No. 201210300046.6, entitled “METHOD OF MANUFACTURING SEMICONDUCTOR DEVICE,” filed on Aug. 21, 2012, which is incorporated herein by reference in its entirety.

### TECHNICAL FIELD

The present disclosure relates to the field of manufacture of semiconductor integrated circuits, and particularly, to manufacturing and etching of a contact hole with a great depth-to-width ratio in silicon nitride.

### BACKGROUND

Etching of contact holes is a key technique for very large scale integrated circuits. As the CMOS technology goes beyond the 32 nm node, etching and filling of contact holes with a great depth-to-width ratio have significant impacts on the yield of resultant devices. Especially, the depth-to-width ratio has become 40:1 or even greater for advanced memory devices, and thus becomes more challenging.

In conventional CMOS devices, contact holes are etched generally in the dielectric material of silicon dioxide. Silicon nitride, as another widely used dielectric material, is hardly used for interlayer dielectric (ILD) layers because of its high K value and great stress. It is commonly used for hard masks, and stop layers for etching or CMP. However, it finds applications in group III-V photoelectric devices with further development of the semiconductor technology.

Etching of thin films of silicon oxide or silicon nitride is generally achieved by means of fluorocarbon gases such as CF₄, CHF₃, CH₂F₂, and CH₃F. To etch deep holes with a steep profile in silicon oxide, gases having long carbon-chain molecules, such as C₄F₆ and C₄F₈, at a high power are usually adopted. However, silicon nitride has a bond energy weaker than that of silicon oxide, and has characteristics between silicon oxide and silicon. If it is desired to etch holes with a great depth-to-width ratio in silicon nitride, then there should be a good control of the fluorocarbon gases. Further, the large carbon-chain molecules will result in a great amount of polymers, which helps etching of deep holes which are relatively steep. On the other hand, it is necessary to effectively remove the polymers on side walls of the holes by means of oxidizing gases such as O₂, to prevent the etching inhibitor from being accumulated too much in the deep holes.

Further, as the technology continues to advance under the Moore's Law, the critical dimension (CD) for the holes has reached the magnitude of 100 nm. It is impossible to manufacture so small-sized holes in silicon nitride if without advanced photolithography processes. In one word, the existing techniques for etching contact holes with a great depth-to-width ratio are deficient, and there is a need for further improving the steepness of etched contact holes and the filling rate of insulating dielectric materials therein, to ensure the reliability of resultant devices.

### SUMMARY

In view of the above, the present disclosure aims to provide, among others, a method of etching a contact hole, by which it is possible to improve a steepness of side walls, and a depth-to-width ratio of the contact hole, and also to enhance a filling rate of insulating dielectric material(s) therein, thereby improving the reliability of a resultant device.

According to an aspect of the present disclosure, there is provided a method of manufacturing a semiconductor device, comprising: etching a plurality of first openings in an interlayer dielectric layer on a substrate; forming an opening modifying layer in the plurality of first openings; and etching the opening modifying layer until the substrate is exposed, resulting in a plurality of second openings, wherein the second openings have a depth-to-width ratio greater than that of the first openings.

In an example of the present disclosure, the interlayer dielectric layer may comprise silicon oxide, silicon nitride, a low-K material, or any combination thereof.

In a further example of the present disclosure, the opening modifying layer may comprise silicon nitride.

In a further example of the present disclosure, the opening modifying layer can be deposited by means of LPCVD or PECVD.

In a further example of the present disclosure, the opening modifying layer can be etched by means of plasma dry-etching with etching gases including a fluorocarbon gas and an oxidizing gas.

In a further example of the present disclosure, the fluorocarbon gas may comprise CF₄, CHF₃, CH₃F, CH₂F₂, or any combination thereof.

In a further example of the present disclosure, the fluorocarbon gas may comprise a first type of fluorocarbon gas and a second type of fluorocarbon gas, wherein the first type of fluorocarbon gas has a carbon-to-fluorine ratio less than that of the second type of fluorocarbon gas.

In a further example of the present disclosure, the first type of fluorocarbon gas may comprise CF₄, CHF₃, CH₃F, CH₂F₂, or any combination thereof, and the second type of fluorocarbon gas may comprise C₄F₆, CH₄F₈, or any combination thereof.

In a further example of the present disclosure, the oxidizing gas may comprise CO, O₂, or any combination thereof.

In a further example of the present disclosure, the interlayer dielectric layer can be etched by means of plasma dry-etching with an etching gas comprising C₄F₆, C₄F₈, or any combination thereof.

In a further example of the present disclosure, there may be an underlying structure in and/or on the substrate, which is exposed by the plurality of first openings and/or the plurality of second openings.

In a further example of the present disclosure, the opening modifying layer can be etched in an Exelan HPt etcher from LAM or a Primo DRIE etcher from AMEC, using two RF systems.

According to embodiments of the present disclosure, a deep hole with a relatively large dimension can be formed in silicon oxide by conventional photolithography processes. After that, a film of silicon nitride can be deposited into the hole to achieve a desired CD, and then etched with the fluorocarbon gas(es) to implement an arrangement with a relatively great depth-to-width ratio.

### BRIEF DESCRIPTION OF THE DRAWINGS

Hereinafter, exemplary embodiments of the present disclosure will be described in detail with reference to attached drawings, in which

FIGS. 1-3 are cross-sectional views schematically showing a process of manufacturing a semiconductor device according to an embodiment of the present disclosure; and

FIG. 4 is a flow chart showing a method of manufacturing a semiconductor device according to an embodiment of the present disclosure.

### DETAILED DESCRIPTION

Hereinafter, exemplary embodiments of the present disclosure will be described in detail with reference to attached drawings. It is to be noted that like symbols denote like structures throughout the drawings. Here, terms, such as “first,” “second,” “on,” “below,” “thick,” and “thin,” are used to describe various device structures. However, such descriptions are not intended to imply relationships of the described device structures in terms of space, order or layer-level, unless otherwise indicated.

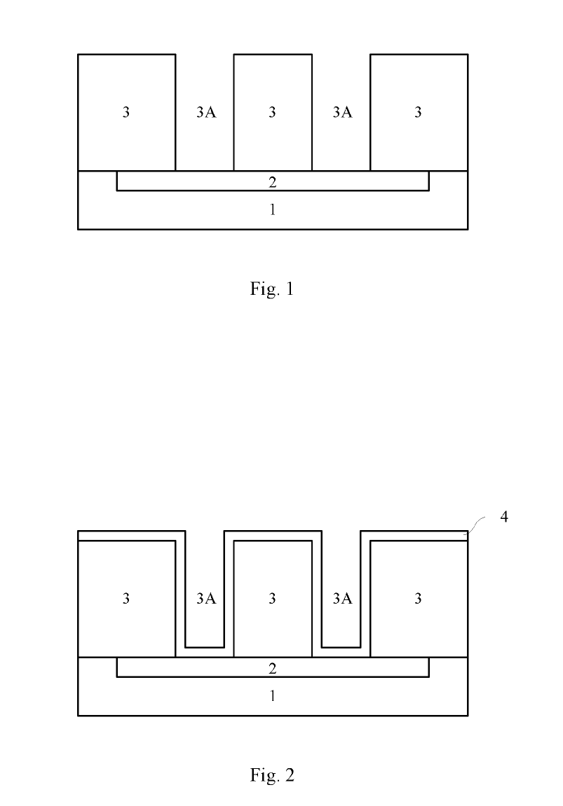

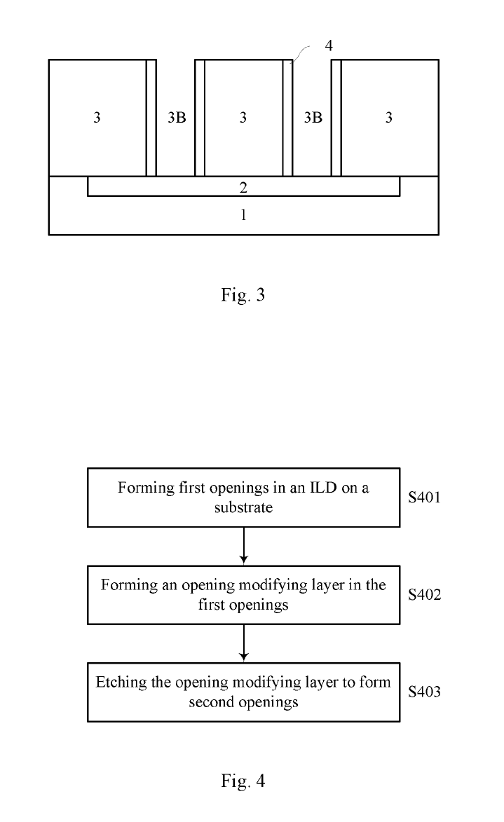

Referring to FIG. 4 and FIG. 1, at 8401, a plurality of first openings 3A are etched in an interlayer dielectric layer 3 on a substrate 1.

The substrate 1 is provided, and may comprise bulk Si, SOI, bulk Ge, GeOI, SiGe, GeSb, or a group III-V or group II-VI compound semiconductor substrate, such as GaAs, GaN, InP, and InSb. To be compatible with the existing CMOS processes and applicable to manufacture of large scale digital integrated circuits, the substrate 1 preferably comprises bulk Si or SOL A plurality of underlying structures 2 may be formed in and/or on the substrate 1 by means of known semiconductor device manufacture processes (for example, those compatible with CMOS). For example, the underlying structures 2 may comprise a source/drain region, metal suicide on the source/drain region, or a gate in a case of MOSFETs, or an underlying interconnection line (e.g., an underlying one in a multi-level interconnection arrangement, or a contact pad) in a case of integrated circuits, or a MOSFET source or drain terminal of a memory cell or an electrode of a passive device such as capacitor in the cell in a case of memory arrays, or an etching stop layer for protecting other structures (e.g., a contact etching stop layer (CESL) in a gate last process, or an etching stop layer between interconnection levels). In FIG. 1, the underlying structure 2 is shown as being formed in the substrate 1 and close to an upper surface of the substrate 1. However, the present disclosure is not limited thereto. The underlying structure 2 can be formed over the upper surface of the substrate 1 (as, e.g., a gate protruded with respect to the upper surface of the substrate), or on a lower surface of the substrate 1. Further, though the underlying structure 2 is shown in FIG. 1 as a continuous one, it can be divided into several portions based on a desired layout, such as source and drain regions of a MOSFET, or different wiring levels.

The interlayer dielectric (ILD) layer 3 is formed on the substrate 1. The ILD layer 3 may comprise silicon oxide, silicon nitride, a low-K material, or any combination thereof (in a mixed manner or a stacked manner). The low-K material may comprise, but not limited to, an organic low-K material (such as one including an aromatic base or a multi-membered ring), an inorganic low-K material (such as an amorphous carbon nitride film, a polycrystal boron nitride film, fluorosilicate glass, BSG, PSG, BPSG), or a porous low-K material (such as a porous silsesquioxane (SSQ) based low-K material, porous silicon dioxide, porous SiOCH, C doped silicon dioxide, porous F doped amorphous carbon, porous diamond, a porous organic polymer). The ILD layer 3 can be formed by means of rapid thermal oxidation (RTO), LPCVD, PECVD, HDPCVD, spin coating, spray coating, screen printing, and the like. The ILD layer 3 has a thickness equal to or greater than that of a contact plug or an interconnection line to be formed.

The ILD layer 3 is etched until the underlying structure 2 is exposed, resulting in the plurality of first openings 3A. The first openings 3A may comprise contact holes (e.g., contact holes to source/drain regions in case of MOSFETs) or trenches (corresponding to, e.g., space for wirings in a wiring level in case of Damascene arrangements). The first openings 3A each may have a depth-to-width ratio preferably greater than 2.5:1, and may have a width greater than an actual opening width to be achieved. For example, the first openings 3A each may have a width of about 180 nm and a depth of about 500 nm. Specifically, the ILD layer 3, if made of silicon oxide, can be subjected to plasma dry-etching with a fluorocarbon gas, such as CF₄, CHF₃, CH₂F₂, and CH₃F, to achieve the openings with a relatively steep profile and a relatively great depth-to-width ratio. To achieve steep openings with an even greater depth-to-width ratio, preferably a fluorocarbon gas having long carbon-chain molecules, such as C₄F₆ and C₄F₈, at a high power can be used. Because the gas such as C₄F₆ and C₄F₈ has a relatively greater carbon-to-fluorine ratio, it can produce a film of silicon-oxygen-carbon-fluorine polymers in a relatively great amount while serving as the etching gas, which is deposited on side and bottom walls of the holes and thus facilitate anisotropic etching of the ILD layer 3 made of silicon oxide or the like.

Referring to FIG. 4 and FIG. 2, at S402, an opening modifying layer 4 may be formed in the plurality of first openings 3A. The opening modifying layer 4 may comprise a material, such as silicon nitride, different from the substrate 1 and the ILD layer 3. The opening modifying layer 4 is provided to modify the steep side walls of the openings and to adjust the depth-to-width ratio of the openings. The opening modifying layer 4 can be achieved by means of LPCVD, PECVD, HDPCVD, and the like, and preferably LPCVD. The opening modifying layer 4 may have a thickness determined substantially by a difference between the width of the first openings 3A and the width of respective second openings 3B (as shown in FIG. 3) to be achieved. For example, if the opening modifying layer 4 has a thickness of about 100 nm, then the width of the respective second openings 3B is 80 nm, increasing the depth-to-width ratio from 2.67:1 to 6.25:1. It is to be noted that the opening modifying layer 4 may comprise any suitable insulating material different from the substrate 1 and the ILD layer 3, though it is described as comprising silicon nitride in the exemplary embodiment, provided that it can provide a relatively high etching selectivity with respect to adjacent layers. Here, the etching selectivity means different etching rates at the same etching gas or (even more) different etching rates at different etching gases.

Referring to FIG. 4 and FIG. 3, at S403, the opening modifying layer 4 can be etched until the substrate 1 or the underlying structure 2 is exposed, resulting in a plurality of second openings 3B. The etching is achieved by plasma dry-etching, preferably.

According to an example of the present disclosure, the etching can be performed in an apparatus such as an Exelan HPt etcher from LAM, using two RF systems, wherein one is at a higher frequency of 27 MHz for generating plasma and adjusting the density of the plasma, and the other is at a lower frequency of 2 MHz for enhancing the ion energy and the bombardment strength and improving the directionality of the etching. Thus, it is possible to perform optimization based on characteristics of the deep holes to be etched, without changing the profile of the etched holes in other aspects. There are other etcher apparatuses from other manufactures based on the same or like principle, which can achieve similar adjustments and thus also fall into the scope of the present disclosure. Etching gases adopted in the plasma dry-etching may comprise a fluorocarbon gas together with an oxidizing gas. The etching mechanism for silicon nitride is different from that for silicon oxide. If long carbon-chain molecules are adopted for etching silicon nitride as in etching silicon oxide, there tends to be a great amount of polymers, making the side walls rough. Further, a cleaning process of the polymers after etching is difficult to be conducted. Therefore, the silicon nitride film is etched preferably by a fluorocarbon gas containing hydrogen, such as CH₃F, CHF₃, and CH₂F₂. Because there are less polymers produced, not only the etching speed can be enhanced, but also the cleaning process after etching can be controlled more easily. The oxidizing gas such as CO and O₂ is provided as a supplemental way to remove the polymers which have been produced or being produced during the etching process, so as not to stop the etching. In determining the amount of the included oxidizing gas, it is necessary to take its impacts on the removal of the polymers into account so as to achieve a desired CD.

Specifically, gases of CHF₃, CH₂F₂, O₂ and the like are adopted in the etching according to an example. Parameters adopted in the etching process can be set as follows, with respect to the Exelan HPt etcher from LAM, out of various etcher apparatuses from different manufacturers, by way of example. For example, a chamber pressure is maintained at 60 mt, flow rates are set as 30 sccm for CHF₃, 20 sccm for CH₂F₂, 10 sccm for O₂, and 500 sccm for Ar, and the power at the higher and lower frequencies are set as 600 W and 400 W, respectively, to achieve the steep profile.

On the other hand, the steep profile will pose significant challenges on subsequent filling of the etched holes with the great depth-to-width ratio. For convenience of the subsequent process, the holes can be made smaller at the bottom thereof and larger at the top thereof. According to an embodiment, this can be achieved by increasing the flow rate of the fluorocarbon gas such as CH₂F₂ while reducing the flow rate of the oxidizing gas such as O₂. In this way, deposition of the polymers on the side walls will be enhanced, so that lateral etching is suppressed. The polymers deposited at the bottom of the holes can be removed by being bombarded with the high power at the lower frequency, and thus will not prevent the anisotropic etching from continuing. As a result, a slightly oblique profile can be achieved. In this case, process parameters can be set as follows. For example, the chamber pressure is maintained at 60 mt, the flow rates are set as 30 sccm for CHF₃, 25 sccm for CH₂F₂, 8 sccm for O₂, and 500 sccm for Ar, and the power at the higher and lower frequencies are set as 600 W and 400 W, respectively.

According to a further example of the present disclosure, the etching can be achieved by plasma dry-etching, and can be performed in an apparatus such as a Primo DRIE etcher from AMEC, using two RF systems, wherein one is at a higher frequency of 60 MHz for generating plasma and adjusting the density of the plasma, and the other is at a lower frequency of 2 MHz for enhancing the ion energy and the bombardment strength and improving the directionality of the etching. The two systems are decoupled from each other, so as not to impact each other. Thus, it is possible to perform optimization based on characteristics of the deep holes to be etched, without changing the profile of the etched holes in other aspects. There are other etcher apparatuses from other manufactures based on the same or like principle, which can achieve similar adjustments and thus also fall into the scope of the present disclosure.

Etching gases adopted in the plasma dry-etching may comprise a fluorocarbon gas together with an oxidizing gas. The etching mechanism for silicon nitride is different from that for silicon oxide. If only long carbon-chain molecules (with a great carbon-to-fluorine ratio) are adopted for etching silicon nitride as in etching silicon oxide, there tends to be a great amount of polymers, making the side walls rough. Further, a cleaning process of the polymers after etching is difficult to be conducted. Thus, it is generally needed to set a relatively high bias to break the long carbon-chain molecules into fractions, which are easier to be removed by reacting with O₂. As a result, it is possible to achieve a desired profile.

According to some embodiments of the present disclosure, there are at least two types of fluorocarbon gases. One type comprises fluorocarbon gases containing hydrogen, with a relatively low carbon-to-fluorine ratio, such as CH₃F, CHF₃, CH₂F₂, or any combination thereof. If the silicon nitride film is etched with this type of fluorocarbon gas(es), there will be less polymers produced. Thus, not only the etching speed can be enhanced, but also the cleaning process after etching can be controlled more easily. The other type comprises fluorocarbon gases with a relatively great carbon-to-fluorine ratio, such as C₄F₆ and C₄F₈. Due to the relatively great carbon-to-fluorine ratio, this type of fluorocarbon gases can produce a film of silicon-oxygen-carbon-fluorine polymers in a relatively great amount while serving as the etching gas, which is deposited on the side and bottom walls of the holes and thus facilitate anisotropic etching of silicon oxide.

The oxidizing gas, such as CO, O₂, or any combination thereof, is provided as a supplemental way to remove the polymers which have been produced or being produced during the etching process, so as not to stop the etching. In determining the amount of the included oxidizing gas, it is necessary to take its impacts on the removal of the polymers into account so as to achieve a desired CD.

Specifically, gases of C₄F₈, CH₂F₂, O₂ and the like are adopted in the etching according to an example. Parameters adopted in the etching process can be set as follows, with respect to the Primo DRIE etcher from AMEC, out of various etcher apparatuses from different manufacturers, by way of example. For example, a chamber pressure is maintained at 40 mt, flow rates are set as 40 sccm for C₄F₈, 80 sccm for CH₂F₂, 100 sccm for O₂, and 400 sccm for Ar, and the power at the higher and lower frequencies are set as 600 W and 1500 W respectively, to achieve the steep profile.

On the other hand, the steep profile will pose significant challenges on subsequent filling of the etched holes with the great depth-to-width ratio. For convenience of the subsequent process, the holes can be made smaller at the bottom thereof and larger at the top thereof. According to an embodiment, this can be achieved by increasing the flow rate of the fluorocarbon gas with the great carbon-to-fluorine ratio (such as C₄F₈) while reducing the flow rate of the oxidizing gas such as O₂. In this way, deposition of the polymers on the side walls will be enhanced, so that lateral etching is suppressed. The polymers deposited at the bottom of the holes can be removed by being bombarded with the high power at the lower frequency, and thus will not prevent the anisotropic etching from continuing. As a result, a slightly oblique profile can be achieved. In this case, process parameters can be set as follows. For example, the chamber pressure is maintained at 40 mt, the flow rates are set as 50 sccm for C₄F₈, 80 sccm for CH₂F₂, 90 sccm for O₂, and 400 sccm for Ar, and the power at the higher and lower frequencies are set as 600 W and 1500 W, respectively.

The resultant second openings 3B constitute desired contact holes or trenches for interconnection wirings, with a width less than that of the first openings 3A, resulting in an improved depth-to-width ratio. For example, in the case where the first openings 3A each may have a width of about 180 nm and a depth of about 500 nm, the second openings 3B each have a width of about 80 nm if the thickness of the opening modifying layer 4 is about 100 nm. In this way, the depth-to-width ratio is increase from 2.67:1 to 6.25:1. In FIGS. 1-3, the respective layers are schematically drawn for illustrating their positional relationships, but not to scale, and thus cannot be interpreted as limiting the thickness relationships of these layers.

Further, there are many adjustable parameters in the etcher apparatus, and the descriptions are not intended to enumerate etching conditions for various films exclusively or exhaustively. Etching gases can be selected based on different demands and/or different films, and will result in different profiles based on specific conditions. For example, if the polymers are increased in amount (by increasing the flow rate(s) of the fluorocarbon gas(es)), then deep holes with a slightly oblique profile can be achieved, which facilitates subsequent filling of dielectrics into the holes. On the other hand, if the oxidizing gas is increased, then the polymers can be adjusted in amount and thus deep holes with a steep profile can be achieved, which, however, may pose challenges on filling dielectrics into the holes.

Furthermore, in the above embodiments the modifying layer is etched with different etching gases in two different etcher apparatuses. However, the etcher apparatuses and the etching gases can be used interchangeably. For example, the Exelan HPt etcher apparatus from LAM can also use the first type of fluorocarbon gases and the second type of fluorocarbon gases as described above, and the Primo DRIE etcher apparatus from AMEC can also use etching gases with a low carbon-to-fluorine ratio.

In the method according to the present disclosure, a deep hole with a relatively large dimension can be formed in silicon oxide by conventional photolithography processes. After that, a film of silicon nitride can be deposited into the hole to achieve a desired CD, and then etched with the fluorocarbon gas(es) to implement an arrangement with a relatively great depth-to-width ratio.

From the foregoing, it will be appreciated that specific embodiments of the disclosure have been described herein for purposes of illustration, but that various modifications may be made without deviating from the disclosure. In addition, many of the elements of one embodiment may be combined with other embodiments in addition to or in lieu of the elements of the other embodiments. Accordingly, the technology is not limited except as by the appended claims.

1. A method of manufacturing a semiconductor device, comprising:
etching a first opening in an interlayer dielectric layer on a substrate;
forming an opening modifying layer in the first opening; and
etching the opening modifying layer until the substrate is exposed, resulting in a second opening, wherein the second opening has a depth-to-width ratio greater than that of the first opening.

2. The method according to claim 1, wherein the interlayer dielectric layer comprises silicon oxide, silicon nitride, a low-K material, or any combination thereof.

3. The method according to claim 1, wherein the opening modifying layer comprises silicon nitride.

4. The method according to claim 1, wherein the opening modifying layer is deposited by means of LPCVD or PECVD.

5. The method according to claim 1, wherein the opening modifying layer is etched by means of plasma dry-etching with etching gases including a fluorocarbon gas and an oxidizing gas.

6. The method according to claim 5, wherein the fluorocarbon gas comprises CF₄, CHF₃, CH₃F, CH₂F₂, or any combination thereof.

7. The method according to claim 5, wherein the fluorocarbon gas comprises a first type of fluorocarbon gas and a second type of fluorocarbon gas, wherein the first type of fluorocarbon gas has a carbon-to-fluorine ratio less than that of the second type of fluorocarbon gas.

8. The method according to claim 7, wherein the first type of fluorocarbon gas comprises CF₄, CHF₃, CH₃F, CH₂F₂, or any combination thereof, and the second type of fluorocarbon gas comprises C₄F₆, C₄F₈, or any combination thereof.

9. The method according to claim 5, wherein the oxidizing gas comprises CO, O₂, or any combination thereof.

10. The method according to claim 1, wherein the interlayer dielectric layer is etched by means of plasma dry-etching with an etching gas comprising C₄F₆, C₄F₈, or any combination thereof.

11. The method according to claim 1, wherein there is an underlying structure in and/or on the substrate, which is exposed by the first opening and/or the second opening.

12. The method according to claim 1, wherein the opening modifying layer is etched in an Exelan HPt etcher from LAM or a Primo DRIE etcher from AMEC, using two RF systems.

13. The method according to claim 1, wherein etching the first opening comprises etching a plurality of first openings.
